(19) United States
(12) Patent Application Publication
(10) Pub. No.: US 2021/0022267 A1
(43) Pub. Date: Jan. 21, 2021

(54) SMALL FORM-FACTOR PLUGGABLE MODULE

(71) Applicant: Optoway Technology Inc., Hsin Chu (TW)

(72) Inventor: Te-Shu Yu, Hsin Chu (TW)

(73) Assignee: Optoway Technology Inc., Hsin Chu (TW)

(21) Appl. No.: 16/683,274

(22) Filed: Nov. 14, 2019

Related U.S. Application Data
(60) Provisional application No. 62/875,951, filed on Jul. 18, 2019.

(30) Foreign Application Priority Data
Oct. 15, 2019 (TW) 108137089

(51) Int. Cl. H05K 7/20

(52) U.S. Cl. CPC H05K 7/20418

(57) ABSTRACT

A small form-factor pluggable module includes a case. The case is provided with a front plate, a top plate connected with the front plate, a bottom plate connected with the front plate and opposite to the top plate, and two side plates connected with the front plate and opposite to each other. The top plate and the bottom plate are respectively connected between the two side plates. The front plate is provided with at least one first opening. The first opening is suitable for being penetrated by at least one connector. A cross-sectional area of the first opening is larger than a cross-sectional area of the connector at where the connector penetrates the first opening.

### CROSS-REFERENCE TO RELATED APPLICATION

This application claims the priority benefits of U.S. provisional application Ser. No. 62/875,951, filed on Jul. 18, 2019, and Taiwan application serial no. 108137089, filed on Oct. 15, 2019. The entirety of each of the above-mentioned patent applications is hereby incorporated by reference herein and made a part of this specification.

### BACKGROUND

### Technical Field

The disclosure relates to a small form-factor pluggable module and particularly relates to a small form-factor pluggable module that helps dissipate heat of an internal component.

### Description of Related Art

When a conventional small form-factor pluggable module is operating, the electronic devices inside the module may generate high heat. In order to prevent heat from accumulating inside and result in dysfunction of the operation when the whole module is operating, the conventional small form-factor pluggable module dissipates the high heat by guiding heat to a metal surface of the overall module through a thermal pad or a heat sink additionally installed inside. However, since the conventional small form-factor pluggable module only relies on the thermal pad or the heat sink to dissipate heat, the heat dissipation efficiency may be not favorable, which leads to accumulated heat inside the conventional small form-factor pluggable module and results in dysfunction of the operation of the whole module.

### SUMMARY

The disclosure provides a small form-factor pluggable module capable of alleviating heat accumulation inside the whole module of a conventional small form-factor pluggable module due to unfavorable heat dissipation efficiency that results in operation dysfunction of the whole module.

A small form-factor pluggable module according to an embodiment of the disclosure includes a case. The case is provided with a front plate, a top plate connected with the front plate, a bottom plate connected with the front plate and opposite to the top plate and two side plates connected with the front plate and opposite to each other. The top plate and the bottom plate are respectively connected between the two side plates. The front plate is provided with at least one first opening. The first opening is suitable for being penetrated by at least one connector. A cross-sectional area of the first opening is larger than a cross-sectional area of the connector at where the connector penetrates the first opening.

In one embodiment of the disclosure, the cross-sectional area of the first opening is larger than a multiple of the cross-sectional area of the at least one connector at the first opening, the multiple being the number of the at least one connector.

In one embodiment of the disclosure, the first opening is connected with at least two diagonal corners of the front plate.

In one embodiment of the disclosure, the first opening is an inclined opening.

In one embodiment of the disclosure, the first opening is an L-shaped opening.

In one embodiment of the disclosure, the first opening is H-shaped.

In one embodiment of the disclosure, the first opening is provided with at least one penetration part and at least one ventilation part connected with the penetration part, and the penetration part is suitable for being penetrated by the connector.

In one embodiment of the disclosure, the front plate further includes a second opening.

In one embodiment of the disclosure, the first opening and the second opening are parallel to each other.

In one embodiment of the disclosure, the first opening and the second opening are each suitable for being penetrated by the at least one connector.

Based on the above, in the small form-factor pluggable module according to the disclosure, an internal space can communicate with the outside to add a heat convection passage. Accordingly, the heat inside the small form-factor pluggable module can be discharged to facilitate the heat dissipation efficiency and ensure that the operation function of the small form-factor pluggable module is stable and normal.

Several exemplary embodiments accompanied with figures are described in detail below to further describe the disclosure in details.

### BRIEF DESCRIPTION OF THE DRAWINGS

The accompanying drawings are included to provide further understanding, and are incorporated in and constitute a part of this specification. The drawings illustrate exemplary embodiments and, together with the description, serve to explain the principles of the disclosure.

FIG. 1A is a three-dimensional schematic view of a small form-factor pluggable module according to a first embodiment of the disclosure.

FIG. 1B is a front schematic view of the small form-factor pluggable module in FIG. 1A with a part of components being omitted.

FIG. 1C is a view illustrating a relationship between cross-sectional areas of a first opening of the small form-factor pluggable module and a connector penetrating the first opening according to a first embodiment of the disclosure.

FIG. 2A, FIG. 2B and FIG. 2C are respectively front schematic views of small form-factor pluggable modules according to second, third and fourth embodiments of the disclosure.

FIG. 3A and FIG. 3B are front schematic views of small form-factor pluggable modules according to fifth and sixth embodiments of the disclosure.

FIG. 4A and FIG. 4B are front schematic views of small form-factor pluggable modules according to seventh and eighth embodiments of the disclosure.

FIG. 5A and FIG. 5B are front schematic views of small form-factor pluggable modules according to ninth and tenth embodiments of the disclosure.

### DESCRIPTION OF THE EMBODIMENTS

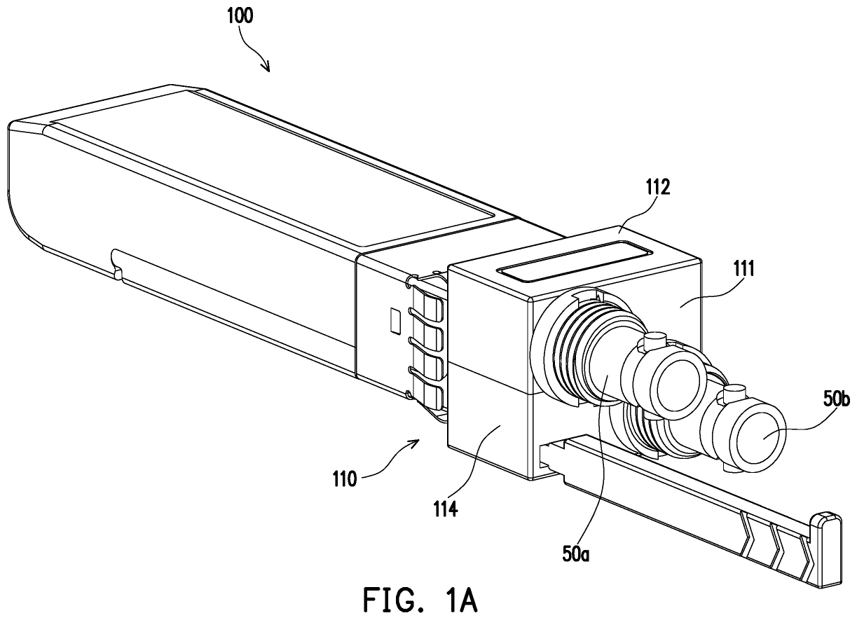

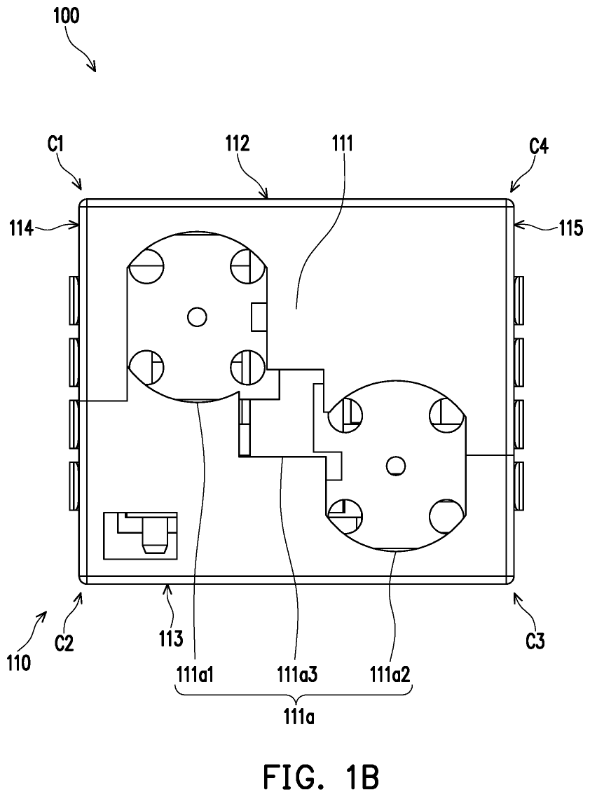

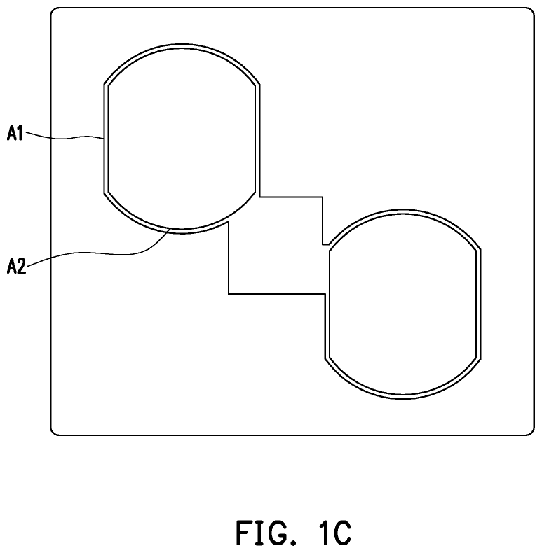

FIG. 1A is a three-dimensional schematic view of a small form-factor pluggable module according to a first embodiment of the disclosure. FIG. 1B is a front schematic view of the small form-factor pluggable module in FIG. 1A with a part of components being omitted. FIG. 1C is a view illustrating a relationship between cross-sectional areas of a first opening of the small form-factor pluggable module and a connector penetrating the first opening according to a first embodiment of the disclosure. Referring to FIG. 1A, FIG. 1B and FIG. 1C, the small form-factor pluggable module 100 according to the present embodiment includes a case 110. The case 110 is provided with a front plate 111, a top plate 112, a bottom plate 113 and two side plates (for example, but not limited to a first side plate 114 and a second side plate 115). All the top plate 112, the bottom plate 113, the first side plate 114 and the second side plate 115 are connected to the front plate 111. The top plate 112 and the bottom plate 113 are opposite, and the first side plate 114 and the second side plate 114 are opposite. The top plate 112 and the bottom plate 113 are connected between the first side plate 114 and the second side plate 115. In other words, the top plate 112 is located at one side of the first side plate 114 and the second side plate 115, while the bottom plate 113 is located at the other side of the first side plate 114 and the second side plate 115.

The front plate 111 is provided with at least one first opening 111a, and the first opening 111a is suitable for being penetrated by at least one connector (for example, but not limited to a first connector 50a and a second connector 50b). As shown in FIG. 1C, a cross-sectional area A1 of the first opening 111a is larger than a cross-sectional area A2 of the connector (for example, but not limited to the first connector 50a or the second connector 50b) at where the connector penetrates the first opening 111a. Therefore, in the small form-factor pluggable module 100 according to the disclosure, the internal space can communicate with the outside to add a heat convection passage. Accordingly, the heat inside the small form-factor pluggable module 100 can be discharged to facilitate the heat dissipation efficiency and ensure that the operation function of the small form-factor pluggable module 100 is stable and normal, and furthermore, the operation dysfunction of the whole module resulting from heat accumulation inside the whole module due to poor heat dissipation of a conventional small form-factor pluggable module is alleviated.

It should be noted that the at least one mentioned by the disclosure refers to no limitation to a number, and the number may be one or more. In addition, the one named as first or second in nouns is for the sake of clear distinction, not intended to limit the number.

Referring to FIG. 1A, FIG. 1B and FIG. 1C, the first opening 111a is provided with at least one penetration part (for example, but not limited to a first penetration part 111a1 and a second penetration part 111a2) and at least one ventilation part (for example, but not limited to a ventilation part 111a3). The ventilation part 111a3 is connected between the first penetration part 111a1 and the second penetration part 111a2. The at least one penetration part is suitable for being penetrated by at least one connector, for example, the first connector 50a penetrates the first penetration part 1111a and the second connector 50b penetrates the second penetration part 111a2, but the disclosure is not limited thereto. In other words, the first penetration part 111a1 may allow the first connector 50a to penetrate, and the second penetration part 111a2 may allow the second connector 50b to penetrate, while the ventilation part 111a3 is configured as a heat dissipation path for communicating the inside of the small form-factor pluggable module 100 with the outside at any time, so that the effect of discharging the heat inside the small form-factor pluggable module 100 can be achieved.

It should be noted that the first penetration part 111a1 and the second penetration part 111a2 may have the same or different cross-sectional shapes, and the first penetration part 111a1 and the second penetration part 111a2 may have the same or different cross-sectional sizes, so as to allow the first connector 50a and the connector 50b having corresponding cross-sectional shapes and sizes to penetrate. The cross-sectional shapes and sizes of the first connector 50a and the second connector 50b are not limited as long as the ventilation part 111a3 is provided as the heat dissipation path for communicating the inside of the small form-factor pluggable module 100 with the outside.

For example, when the first penetration part 111a1 and the second penetration part 111a2 have the same cross-sectional shape and size, the first opening 111a has the cross-sectional area A1, the first connector 50a has the cross-sectional area A2 at where the connector 50a penetrates the first penetration part 111a, and the cross-sectional area A1 of the first opening 111a is larger than, for example, but is not limited to, two times of the cross-sectional area A2 of of the first connector 50a (or the second connector 50b) at the first opening 111a, i.e., A1>2A2 (the cross-sectional area A1 is larger than the cross-sectional areas A2 of N connectors at where the N connectors penetrate the first opening 111a, i.e., A1>NA2). In this way, referring to FIG. 1A and FIG. 1C, when the first connector 50a penetrates the first penetration part 111a1 and the second connector 50b penetrates the second penetration part 111a2, it is ensured that a remaining space may form the ventilation part 111a3, so that the inside of the small form-factor pluggable module 100 can communicate with the outside.

In other embodiments not shown, if only one connector is provided, accordingly, only one penetration part is required, and in this case, it only requires that the cross-sectional area of the first opening is larger than the cross-sectional area the single connector at where the connector penetrates the first opening and the ventilation part is reserved.

The principle of improving the heat dissipation effect of the small form-factor pluggable module according to the disclosure has been described as above. Various feasible configurations for improving the heat dissipation effect of the small form-factor pluggable module will be described as below. It should be noted that various examples disclosed below are merely for illustration, and not intended to limit how the configuration of the disclosure is set.

Referring to FIG. 1A and FIG. 1B, in the small form-factor pluggable module 100 according to the first embodiment of the disclosure, the top plate 112 and the first side plate 114 are connected at a corner C1, the first side plate 114 and the bottom plate 113 are connected at a corner C2, the bottom plate 113 and the second side plate 115 are connected at a corner C3, and the second side plate 115 and the top plate 112 are connected at a corner C4. The first penetration part 111a1 is located on a position, adjacent to the corner C1, of the front plate 111, and the second penetration part 111a2 is located on a position, adjacent to the corner C3, of the front plate 111. In other words, the first opening 111a is connected with at least two diagonal corners of the front plate 111 (for example, but not limited to two diagonal corners, adjacent to the corner C1 and the corner C3, of the front plate 111), so that the first opening 111a is an inclined opening, and there is no limit to which two diagonal corners the first opening 111a is connected with. In addition, both the first penetration part 111a1 and the second penetration part 111a2 have the same cross-sectional shapes and sizes and are substantially in noncircular shapes having unfilled corners at the left and right sides. Moreover, the cross section of the ventilation part 111a3 is square substantially.

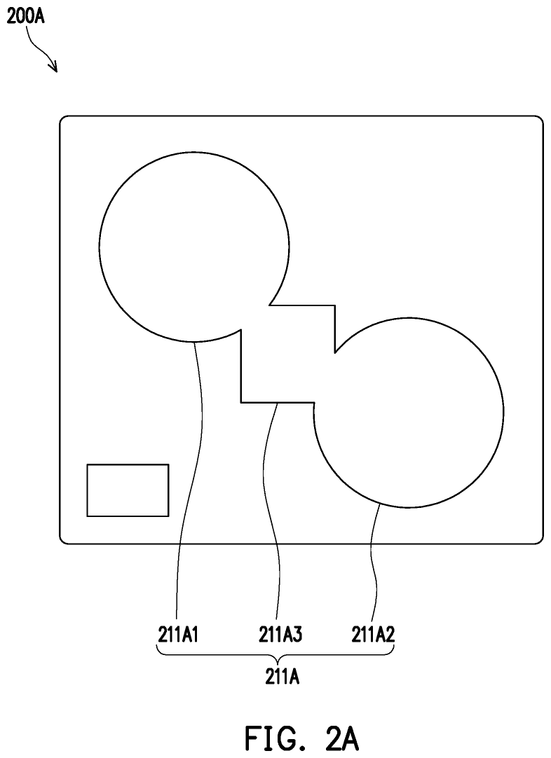

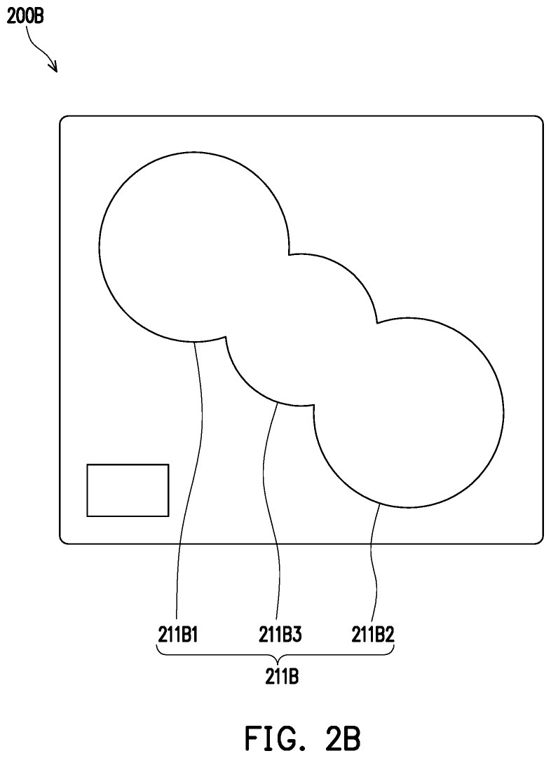

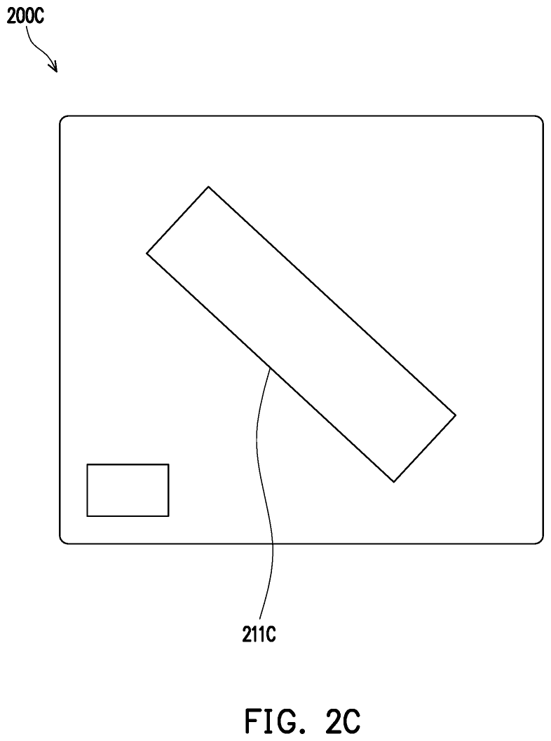

FIG. 2A, FIG. 2B and FIG. 2C are respectively front schematic views of small form-factor pluggable modules according to second, third and fourth embodiments of the disclosure. Referring to FIG. 2A, FIG. 2B and FIG. 2C, in a small form-factor pluggable module 200A according to the second embodiment, a small form-factor pluggable module 200B according to the third embodiment and a small form-factor pluggable module 200C according to the fourth embodiment, each of a first opening 211A, a first opening 211B and a first opening 211C is also connected with two diagonal corners and is an inclined opening. The similarity of these embodiments lies in that, in the small form-factor pluggable module 200A and the small form-factor pluggable module 200B according to the second and third embodiments, cross sections of a first penetration part 211A1, a second penetration part 211A2, a first penetration part 211B1 and a second penetration part 211B2 are all set to be round and same in size.

The difference of the second, third and fourth embodiments lies in that, in the small form-factor pluggable module 200A according to the second embodiment, the cross section of a ventilation part 211A3 is square substantially.

In the small form-factor pluggable module 200B according to the third embodiment, the cross section of a ventilation part 211B3 is substantially round.

In the small form-factor pluggable module 200C according to the fourth embodiment, the first opening 200C is an opening obliquely formed in the front plate and is connected with two diagonal corners of the front plate, although a first penetration part, a second penetration part and a ventilation part are not clearly defined as all the embodiments mentioned above, the first opening 211C is suitable for being penetrated by at least one connector, and has a cross-sectional area larger than a cross-sectional area of the connector at where the connector penetrates the first opening 211C, so that the first opening 211C has a heat dissipation path for communicating the inside with the outside to increase the heat dissipation efficiency.

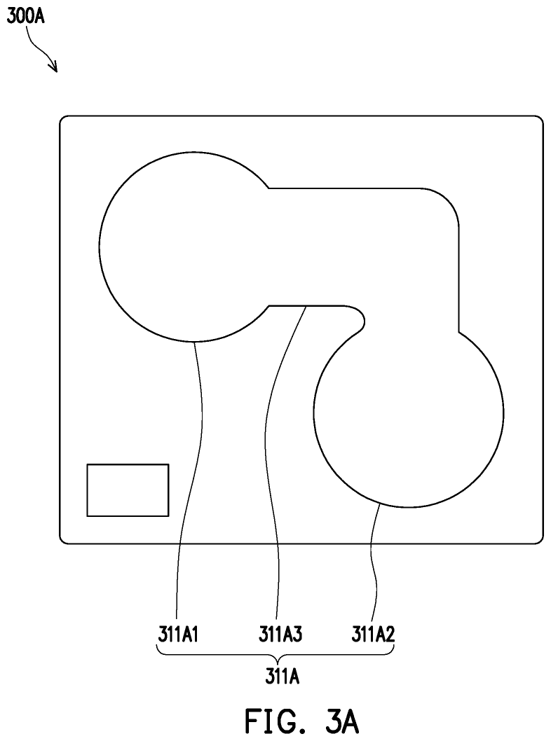

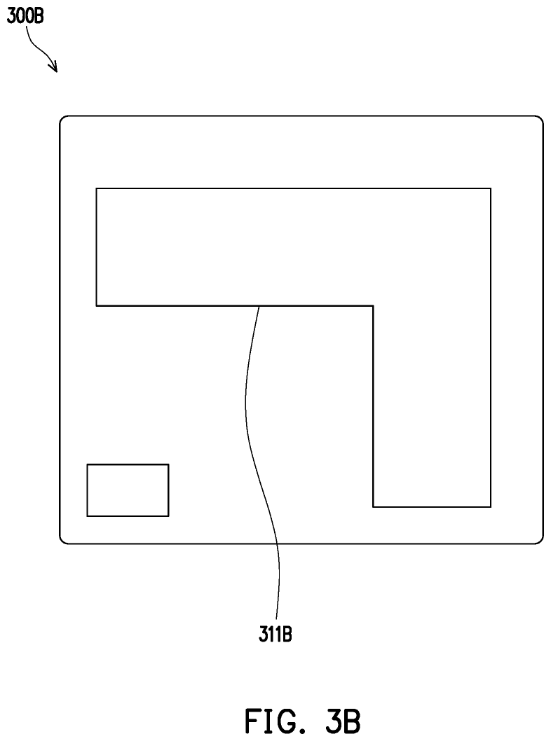

FIG. 3A and FIG. 3B are front schematic views of small form-factor pluggable modules according to fifth and sixth embodiments of the disclosure. Referring to FIG. 3A and FIG. 3B, the similarity of a small form-factor pluggable module 300A according to the fifth embodiment and a small form-factor pluggable module 300B according to the sixth embodiment lies in that, the cross sections of both a first opening 311A and a first opening 311B are substantially L-shaped.

The difference of the fifth and sixth embodiments lies in that, in the small form-factor pluggable module 300A according to the fifth embodiment, the first opening 311A is provided with a first penetration part 311A1 and a second penetration part 311A2 which are respectively located at two diagonal corners and have round cross sections, and a ventilation part 311A3 is L-shaped and is connected with the first penetration part 311A1 and a second penetration part 311A2, so that the first opening 311A can provide the ventilation part 311A3 with a larger cross-sectional area, and furthermore, the heat dissipation effect of the small form-factor pluggable module 300A is further improved.

In the small form-factor pluggable module 300B according to the sixth embodiment, the first opening 311B is L-shaped and is connected with two diagonal corners of the front plate, the first opening 311B is suitable for being penetrated by at least one connector, similar to the fifth embodiment, two connectors respectively penetrate two ends of the L-shaped first opening 311B.

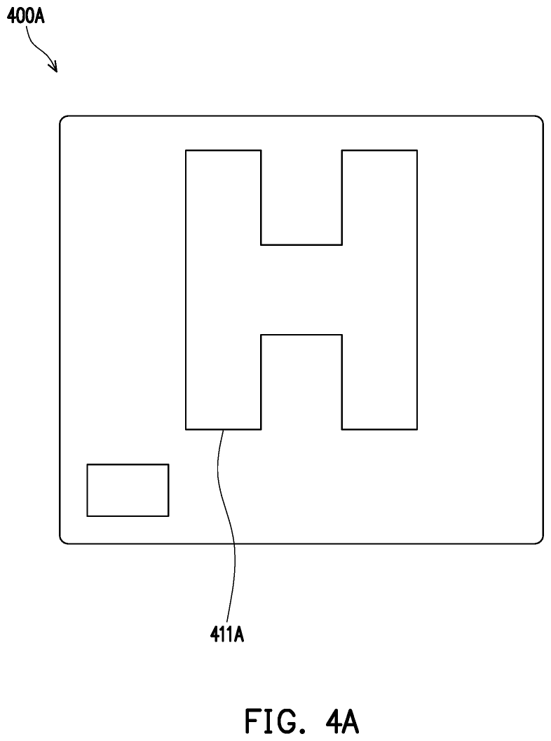

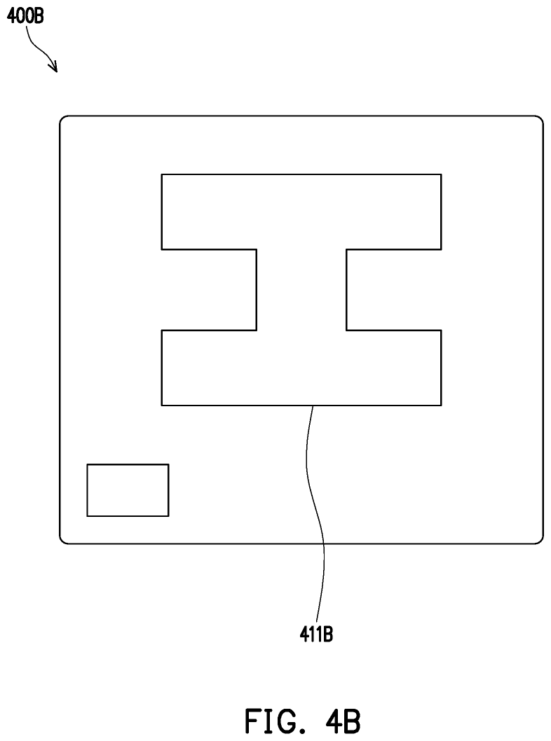

FIG. 4A and FIG. 4B are front schematic views of small form-factor pluggable modules according to seventh and eighth embodiments of the disclosure. Referring to FIG. 4A and FIG. 4B, the similarity of a small form-factor pluggable module 400A according to the seventh embodiment and a small form-factor pluggable module 400B according to the eighth embodiment lies in that, cross sections of a first opening 411A and a first opening 411B are substantially H-shaped. The difference of the small form-factor pluggable module 400A according to the seventh embodiment and the small form-factor pluggable module 400B according to the eighth embodiment lies in that, setting directions of the H-shaped cross sections of the first opening 411A and the first opening 411B are different. A first penetration part, a second penetration part and a ventilation part are not clearly defined as mentioned above in the small form-factor pluggable module 400A according to the seventh embodiment and the small form-factor pluggable module 400B according to the eighth embodiment. Actually, based on the number of connectors and a part that penetrates the first opening 411A and the first opening 411B, a part without being penetrated by connectors of the first opening 411A and the first opening 411B is the ventilation part for communicating the inside of the small form-factor pluggable module 400A and the small form-factor pluggable module 400B with the outside.

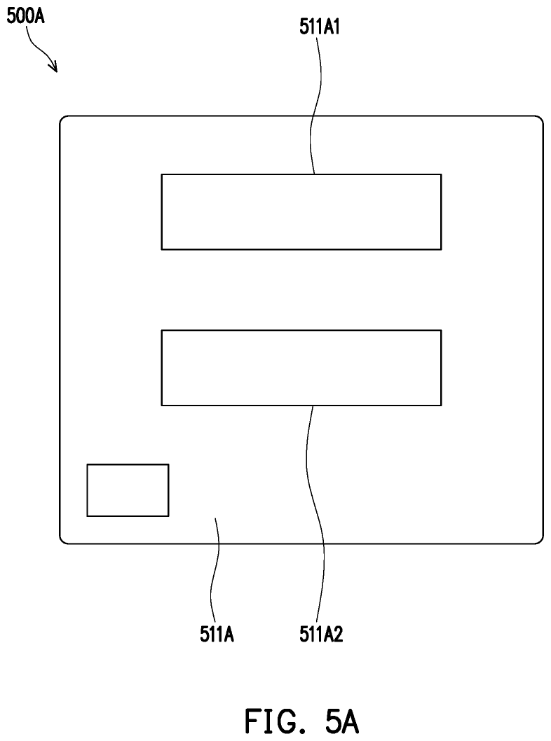

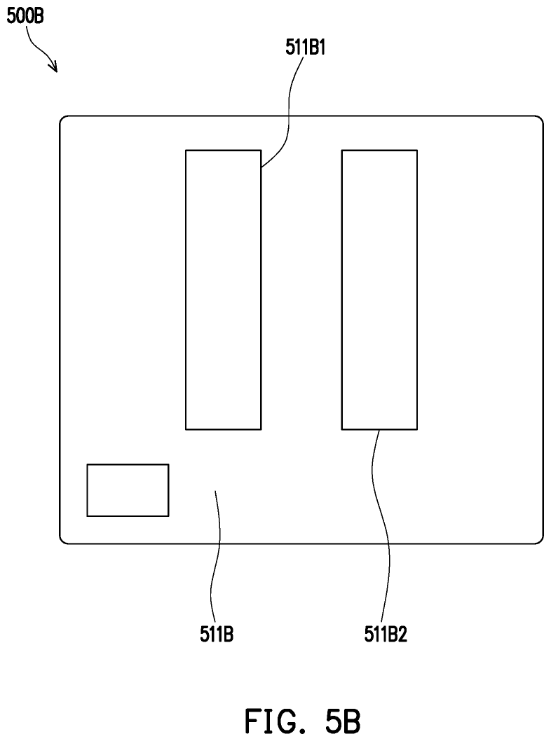

FIG. 5A and FIG. 5B are front schematic views of small form-factor pluggable modules according to ninth and tenth embodiments of the disclosure. Referring to FIG. 5A and

FIG. 5B, the similarity of a small form-factor pluggable module 500A according to the ninth embodiment and a small form-factor pluggable module 500B according to the tenth embodiment lies in that, a front plate 511A and a front plate 511B further include a second opening 511A2 and a second opening 511B2 respectively. A first opening 511A1 and a second opening 511A2 are parallel to each other, and the first opening 511B1 and the second opening 511B2 are parallel to each other. The first opening 511A1, the second opening 511A2, the first opening 511B1 and the second opening 511B2 are each suitable for being penetrated by at least one connector. In other words, each opening may be provided with a ventilation part for heat dissipation.

The difference of the small form-factor pluggable module 500A according to the ninth embodiment and the small form-factor pluggable module 500B according to the tenth embodiment lies in that the first opening 511A1 and the second opening 511A2 are arranged in a horizontal direction, while the first opening 511B1 and the second opening 511B2 are arranged in a vertical direction.

In other embodiments not shown, the first opening and the second opening may be obliquely arranged on the front plate.

Therefore, the ventilation part for communicating the inside of the small form-factor pluggable module with the outside may be correspondingly reserved according to an actual demand for penetrating the connector.

Based on the above, in the small form-factor pluggable module according to the disclosure, an internal space can communicate with the outside to add a heat convection passage.

Accordingly, the heat inside the small form-factor pluggable module can be discharged to facilitate the heat dissipation efficiency and ensure that the operation function of the small form-factor pluggable module is stable and normal, and furthermore, heat accumulation inside the whole module of the conventional small form-factor pluggable module due to unfavorable heat dissipation efficiency that results in operation dysfunction of the whole module is alleviated.

It will be apparent to those skilled in the art that various modifications and variations can be made to the structure of the disclosed embodiments without departing from the scope or spirit of the disclosure. In view of the foregoing, it is intended that the disclosure cover modifications and variations of this disclosure provided they fall within the scope of the following claims and their equivalents.

What is claimed is:

1. A small form-factor pluggable module, comprising:
a case, provided with a front plate, a top plate connected with the front plate, a bottom plate connected with the front plate and opposite to the top plate, and two side plates connected with the front plate and opposite to each other, the top plate and the bottom plate being respectively connected between the two side plates, wherein the front plate is provided with at least one first opening, the first opening is suitable for being penetrated by at least one connector, and a cross-sectional area of the first opening is larger than a cross-sectional area of the connector at where the connector penetrates the first opening.

2. The small form-factor pluggable module according to claim 1, wherein the cross-sectional area of the first opening is larger than a multiple of the cross-sectional area of the at least one connector at the first opening, the multiple being the number of the at least one connector.

3. The small form-factor pluggable module according to claim 1, wherein the first opening is connected with at least two diagonal corners of the front plate.

4. The small form-factor pluggable module according to claim 3, wherein the first opening is an inclined opening.

5. The small form-factor pluggable module according to claim 3, wherein the first opening is an L-shaped opening.

6. The small form-factor pluggable module according to claim 3, wherein the first opening is H-shaped.

7. The small form-factor pluggable module according to claim 1, wherein the first opening is provided with at least one penetration part and at least one ventilation part connected with the penetration part, and the penetration part is suitable for being penetrated by the connector.

8. The small form-factor pluggable module according to claim 1, wherein the front plate further comprises a second opening.

9. The small form-factor pluggable module according to claim 8, wherein the first opening and the second opening are parallel to each other.

10. The small form-factor pluggable module according to claim 9, wherein the first opening and the second opening are each suitable for being penetrated by the at least one connector.
